(19) United States
(12) Patent Application Publication
(10) Pub. No.: US 2025/0203819 A1
(43) Pub. Date: Jun. 19, 2025

(54) SIGNAL CONDITIONING CONNECTOR ASSEMBLY WITH THERMAL MANAGEMENT

(71) Applicant: Microsoft Technology Licensing, LLC, Redmond, WA (US)

(72) Inventor: Jason David ADRIAN, Woodinville, WA (US)

(73) Assignee: Microsoft Technology Licensing, LLC, Redmond, WA (US)

(21) Appl. No.: 18/613,021

(22) Filed: Mar. 21, 2024

Related U.S. Application Data
(60) Provisional application No. 63/609,759, filed on Dec. 13, 2023.

(51) Int. Cl. H05K 7/20

(52) U.S. Cl. CPC H05K 7/2039; H05K 7/20218

(57) ABSTRACT

A signal conditioning connector assembly is provided, including an enclosure, and a plurality of signal conditioner layers mounted within the enclosure. Each signal conditioner layer includes a substrate, signal conditioner circuitry mounted to the substrate, first electrodes forming a first connector on a first side of the signal conditioner circuitry, second electrodes forming a second connector on a second side of the signal conditioner circuitry, a heat spreader in thermal communication with a side of the signal conditioner circuitry opposite the substrate, and a liquid cooling pipe positioned adjacent and in thermal communication with the heat spreader. The liquid cooling pipe is configured to draw heat away from the heat spreader for thermal management. The signal conditioning connector assembly can be positioned adjacent an interface between the vertical cable shuffle and the horizontal cable backplane within the rack of the computing device assembly of the first and second aspects.

### CROSS REFERENCE TO RELATED APPLICATIONS

This application claims priority to U.S. Provisional Patent Application Ser. No. 63/609,759, filed Dec. 13, 2023, the entirety of which is hereby incorporated herein by reference for all purposes.

### BACKGROUND

Modern computing increasingly takes place in data center environments. Particularly with the rise of large machine learning (ML) models, the need for increased compute power has risen dramatically. The cost of deploying and operating compute units used to handle computing tasks such as model training and inference is significant. Further, the compute time required to train large ML models can be lengthy and costly. As a result, technical challenges exist to improve data center hardware, to increase performance and control costs, for the increasing compute demands of the modern ML era. Further, as data transfer rates in computing hardware such as data center server racks increase, the signal integrity can suffer. A loss of signal integrity can result in data transmission errors, which can frustrate training of ML models, as one example. Often, the only solution to such data transmission errors at high data transfer rates is to configure the hardware for slower data transmission rates to ensure fidelity of transmissions, resulting in longer training and inference compute times.

### SUMMARY

To address the above issues, a computing device assembly is provided. According to a first aspect, a computing device assembly is provided, including a rack, and a plurality of compute units that are horizontally oriented and mounted within the rack in one of two vertical stacks. The computing device assembly further includes a plurality of switches that are vertically oriented and mounted along a front side of the rack laterally between the two vertical stacks of compute units. The computing device assembly further includes a plurality of horizontal cable backplanes mounted in a vertical stack along a rear side of the rack. The computing device assembly further includes a plurality of vertical cable shuffles mounted between the two vertical stacks of compute units and between the vertically oriented switches and the vertical stack of horizontal cable backplanes.

According to a second aspect, the computing device assembly includes a rack defining a rectangular volume, a plurality of compute units, each computing unit being horizontally oriented and mounted within the rack in one of two vertical stacks positioned on opposite lateral sides of the rack. The computing device assembly further includes a plurality of switches, each switch being vertically oriented and mounted within the rack along a front side of the rack laterally between the two vertical stacks of compute units, in one of a plurality of groups positioned at respective vertical levels. The computing device assembly further includes a plurality of horizontal cable backplanes mounted in a vertical stack along a rear side of the rack, each horizontal cable backplane containing cables that electrically interconnect a compute unit from the first stack, a compute unit from the second stack and a switch at a corresponding vertical level. The computing device assembly further includes a plurality of vertical cable shuffles mounted within the rack so as to be between the two vertical stacks of compute units in a lateral dimension, and between the vertically oriented groups of switches and the vertical stack of horizontal cable backplanes in a depth dimension, each vertical cable shuffle including cables that electrically interconnect each of a plurality of connections on a corresponding switch from each of the groups of switches to corresponding connections on each of the horizontal cable backplanes.

According to a third aspect, a signal conditioning connector assembly is provided, including an enclosure, and a plurality of signal conditioner layers mounted within the enclosure. Each signal conditioner layer includes a substrate, signal conditioner circuitry mounted to the substrate, first electrodes forming a first connector on a first side of the signal conditioner circuitry, second electrodes forming a second connector on a second side of the signal conditioner circuitry, a heat spreader in thermal communication with a side of the signal conditioner circuitry opposite the substrate, and a liquid cooling pipe positioned adjacent and in thermal communication with the heat spreader. The liquid cooling pipe is configured to draw heat away from the heat spreader for thermal management. In some configurations, the signal conditioning connector assembly can be positioned adjacent an interface between the vertical cable shuffle and the horizontal cable backplane within the rack of the computing device assembly of the first and second aspects.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a perspective view of a computing device assembly according to an example implementation.

FIG. 2 is a perspective view of another example of a computing device assembly similar to FIG. 1, with power conversion units mounted in mounting bays adjacent lateral sides of the rack.

FIG. 3 is a schematic top view of an arrangement of components within the rack of FIG. 1.

FIG. 4 is a partial schematic rear view of an arrangement of components within the rack of FIG. 1.

FIG. 5 is a schematic side view of an arrangement of components within the rack of FIG. 1, taken along the cross section indicated at line 5-5 in FIG. 3.

FIG. 6 is a schematic side view of an arrangement of components within the rack of FIG. 1, including internal cabling within a vertical cable shuffle, taken along the cross section indicated at line 6-6 in FIG. 3.

FIG. 7A shows a solid perspective view of the rack, FIG. 7B shows a front view of the rack, FIG. 7C shows a perspective view of the horizontal cable backplane, and FIG. 7D shows a partially transparent perspective view of the computer device assembly of FIG. 1.

FIG. 8A shows a solid perspective view of the vertical cable shuffle with an example cable illustrated therein, FIG. 8B shows a partially transparent perspective view of the computer device assembly of FIG. 1, with the horizontal cable backplane and vertical cable shuffle installed, FIG. 8C shows a solid perspective view of a compute unit, and FIG. 8D shows a partially transparent perspective view of the computing device assembly of FIG. 1 with the compute units, vertical cable shuffle, and horizontal cable backplanes installed.

FIG. 9A shows a solid perspective view of the vertically oriented switch, FIG. 9B shows a partially transparent perspective view of the computer device assembly of FIG. 1, with 48×2=96 compute units installed similarly to FIG. 1, and FIG. 9C shows a modified version of the configuration of FIG. 9B with 32×2=64 compute units installed.

FIG. 10 shows a side view of an alternative configuration of the computing device assembly of FIG. 3, taken along line 10-10, showing signal conditioner connector assemblies installed within the vertical cable shuffle, to improve signal integrity, particularly at high data transfer rates.

FIG. 11 shows a partial exploded schematic side view of the alternative configuration of the computing device assembly shown in FIG. 10, schematically illustrating a signal conditioner connector assembly in detail.

FIG. 12 shows a rear view of the signal conditioner connector assembly of FIGS. 10 and 11, showing internal details.

FIG. 13 shows a schematic side view of the signal conditioner connector assembly of FIGS. 10-12, showing internal details.

FIG. 14 is a side view of the vertical cable shuffle, showing a path of a liquid cooling pipe to cool the signal conditioner assemblies.

### DETAILED DESCRIPTION

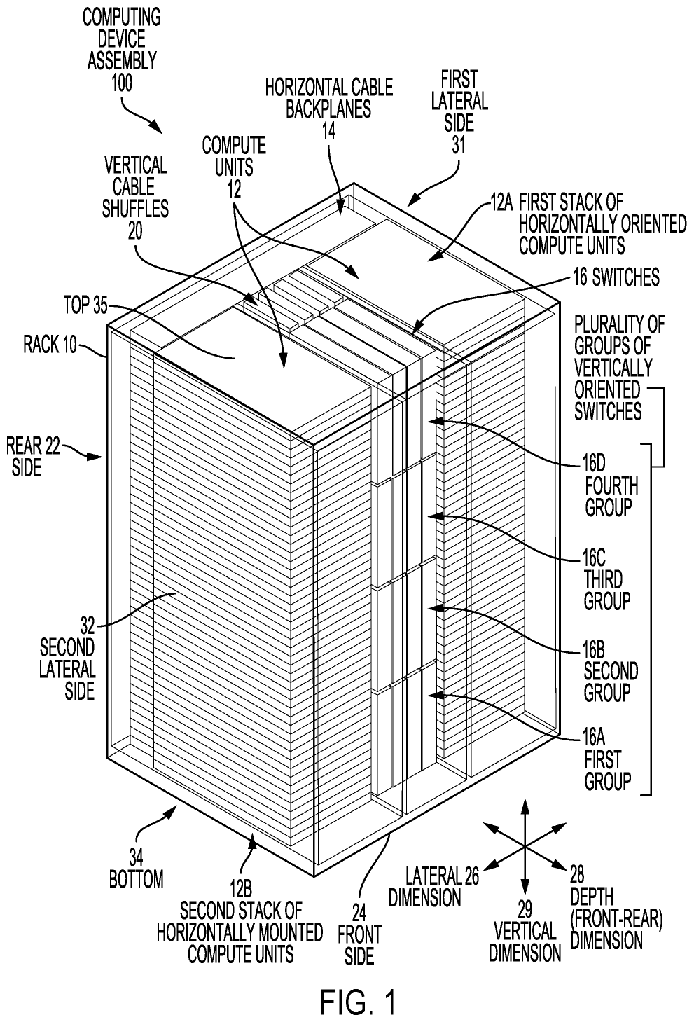

Turning initially to FIG. 1, a computing device assembly 100 is illustrated. The computing device assembly 100 includes a rack 10 defining a rectangular volume. The computing device assembly 100 further includes a plurality of compute units 12, each compute unit 12 being horizontally oriented and mounted within the rack 10 in one of two vertical stacks 12A, 12B positioned on opposite lateral sides 31, 32 of the rack 10. For example, the compute units 12 may be hardware accelerator units such as graphical processor units (GPUs), tensor processing units (TPUs), or field programmable gate array (FPGA) units. Alternatively, the compute units 12 may be central processing units (CPUs) of server devices. If desired, a mix of these or other types of compute units 12 may be utilized within the computing device assembly 100. The data connectors for the compute units 12 face a rear side 22 of the rack 10. The compute units 12 are mounted in a manner such that the rear faces of the compute units 12 are inset a predetermined distance from the rear of the rack 10, thus providing space for horizontal cable backplanes 14. The two vertical stacks 12A, 12B of the compute units 12 are spaced apart in a lateral dimension 26 by a gap within which other components, discussed below, are placed. The compute units 12 have a rectangular plate shape, and are elongated in the lateral dimension 26 and depth dimension 28. As viewed from above, the lateral dimension 26 of each of the compute units 12 is approximately ¼ to ⅓ of the lateral dimension 26 of the rack 10, while the depth dimension 28 of each of the compute units 12 is approximately 60-90% and in some cases 70-80% of the depth dimension 28 of the rack 10. The outer dimensions of each of the compute units 12 is typically the same.

The computing device assembly 100 further includes a plurality of switches 16, each switch 16 being vertically oriented and mounted within the rack 10 along a front side 24 of the rack 10 laterally between the two vertical stacks 12A, 12B of compute units 12, in one of a plurality of groups positioned at respective vertical levels. In the depicted embodiment, four groups 16A-16D of switches 16 are illustrated, each at a different level in a vertical dimension 29 of the rack 10. The data connections for the switches 16 are formed on a rear side of the switches 16. The switches 16 are generally the same size, each being elongated in the depth and vertical dimensions 28, 29 of the rack 10, as mounted.

The computing device assembly 100 further includes a plurality of horizontal cable backplanes 14 mounted in a vertical stack along the rear side 22 of the rack 10, each horizontal cable backplane 14 containing cables that electrically interconnect the data connections on the compute unit 12 from the first stack 12A, the compute unit 12 from the second stack 12B and the switch 16 at a corresponding vertical level. The horizontal cable backplanes 14 extend over substantially an entire lateral dimension of the rack 10, and the data connections for the horizontal cable backplanes 14 are positioned to face the front side 24 of the rack 10, thus facing the data connections on the rear side of the compute units 12.

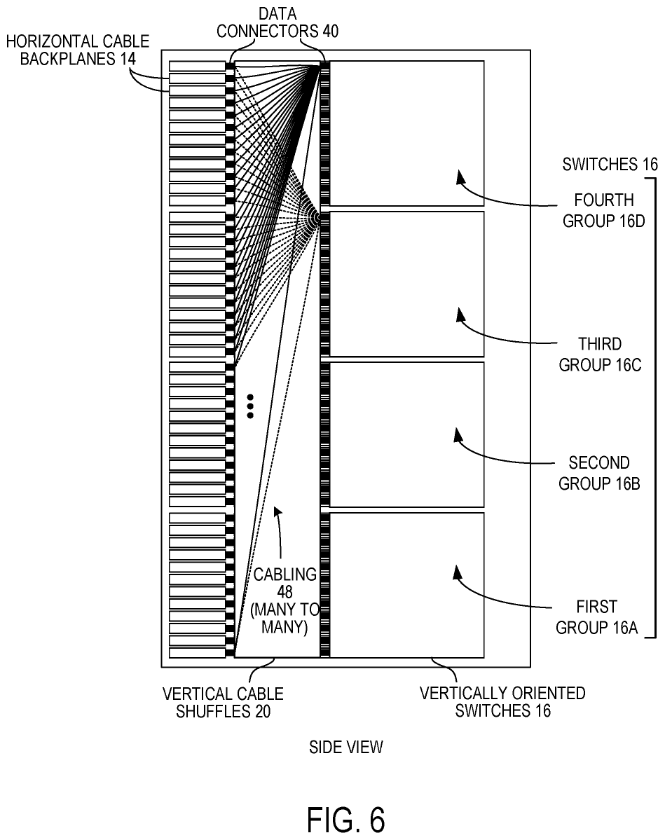

The computing device assembly 100 further includes a plurality of vertical cable shuffles 20 mounted within the rack 10 so as to be between the two vertical stacks 12A, 12B of compute units 12 in the lateral dimension 26, and between the vertically oriented groups 16A-16D of switches 16 and the vertical stack of horizontal cable backplanes 14 in the depth dimension 28. Each of the vertical cable shuffles 20 includes cables that electrically interconnect data connections of each of a plurality of data connections on a corresponding switch from each of the groups 16A-16D of switches 16 to corresponding data connections on each of the horizontal cable backplanes 14. The vertical cable shuffles 20 typically include housings of folded sheet metal with internal cabling 48 (see FIG. 6). The vertical cable shuffles 20 are elongated in the depth and vertical dimensions 28, 29 of the rack 10, and have a minor axis in the lateral dimension 26. Data connections on the vertical cable shuffles 20 face both the rear side 22 of the rack 10 and the front side 24 of the rack 10.

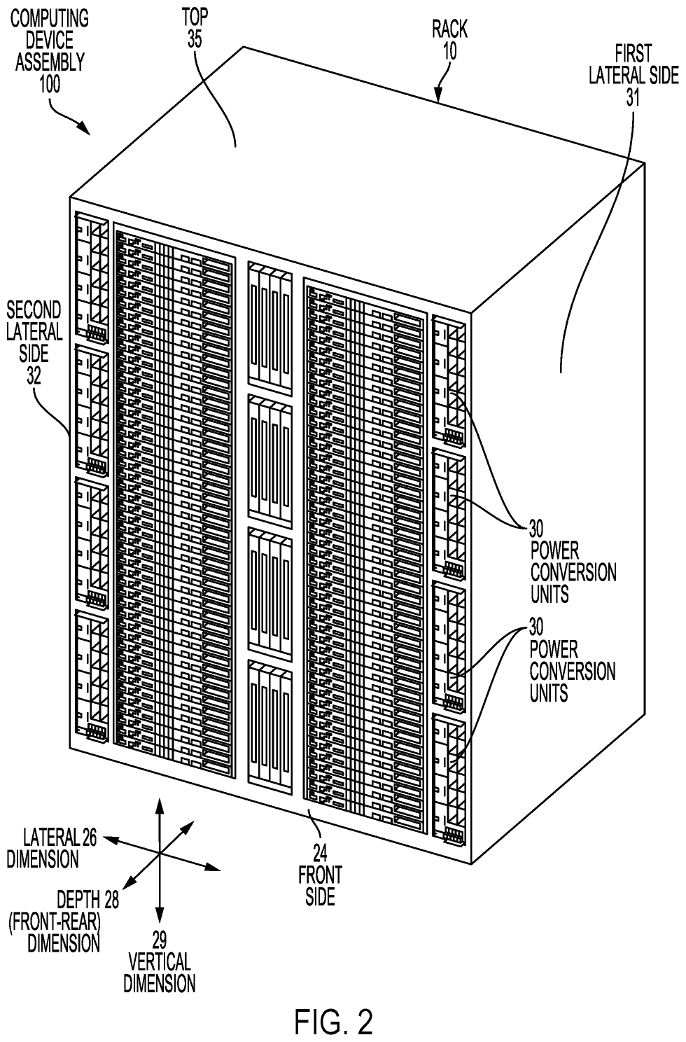

FIG. 2 is a perspective view of another example of a computing device assembly 100 similar to FIG. 1. As shown in FIG. 2, the configuration of the illustrated computing device assembly 100 includes power conversion units 30 (e.g., AC/DC converters) mounted in mounting bays adjacent lateral sides 31, 32 of the rack 10. Alternatively, the power conversion units 30 may be mounted in bays provided adjacent a bottom 34 or a top 35 of the rack 10 and a smaller number of compute units 12 may be included in the rack 10, for example.

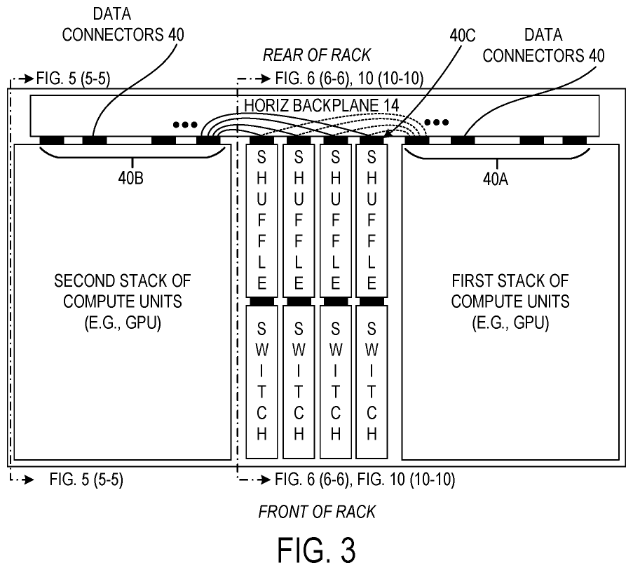

FIG. 3 is a schematic top view of an arrangement of components within the rack 10 of FIG. 1. The horizontal cable backplane 14 includes a sheet metal enclosure with data connectors 40 positioned on a front facing (i.e., compute unit and vertical cable shuffle facing) side of the enclosure. The connectors 40 within the horizontal cable backplane 14 are divided into a set of first compute unit connectors 40A, a set of second compute unit connectors 40B and a set of shuffle connectors 40C. It will be appreciated that each of the connectors in the set of first compute unit connectors 40A is connected by cabling to each of the connectors in the set of shuffle connectors 40C, in a many-to-many fashion, as illustrated in dashed lines. Further, each of the connectors in the set of second compute unit connectors 40B is also connected by cabling to each of the connectors in the set of shuffle connectors 40C, in a many to many fashion, as illustrated in solid lines. The cabling in the horizontal cable backplane 14 is typically shielded copper wire, although other cabling may be used. In this view the data connections between the vertical cable shuffle 20 and switches 16 can also be seen. The number of data connections on the compute units 12, switches 16, and vertical cable shuffles 20 is exemplary, as other numbers of connections may be provided.

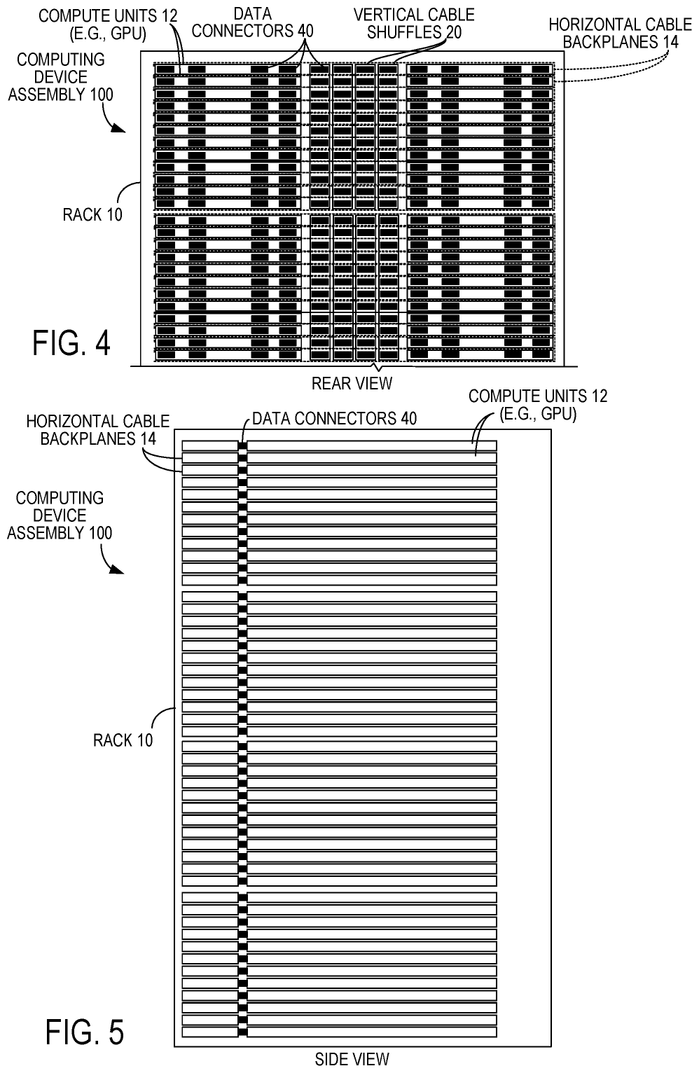

FIG. 4 is a partial schematic rear view of an arrangement of components within the rack 10 of FIG. 1. The horizontal cable backplane 14 is shown in dashed line in this view, enabling the connectors 40 on the compute units 12 and vertical cable shuffles 20 to be seen.

FIG. 5 is a schematic side view of the computing device assembly 100 of FIG. 1, taken along the cross section indicated at line 5-5 in FIG. 3. In this view, the side view of the horizontal cable backplane 14 is visible, as is the side view of each of the compute units 12, and the data connector 40 between these components.

FIG. 6 is a schematic side view of the computing device assembly 100 of FIG. 1, illustrating the internal cabling 48 within the vertical cable shuffles 20. The view in FIG. 6 is taken along the cross section indicated at line 6-6 in FIG. 3. As shown, cabling 48, typically in the form of shielded copper wire, is provided connecting each data connector 40 on each vertically mounted switch 16 in each switch group 16A, 16B, 16C, 16D to respective data connectors 40 on each of the horizontal cable backplanes 14 to which the vertical cable shuffle 20 is connected. This results in a many-to-many cabling configuration, illustrated in solid and dashed lines for exemplary data connectors 40. By providing a vertical cable shuffle 20 with cabling 48 connecting the switches 16 to each of the respective data connectors 40 on the horizontal cable backplanes 14, the combination of the horizontal cable backplane 14 and vertical cable shuffle 20 (which acts as a vertical backplane) enables the switches 16 to route requests and responses to and from any of the compute units 12 within the rack 10 of the computing device assembly 100. This size and configuration of the horizontal and vertical backplanes 14, 20, computing units 12, and switches 16, enables data transfer rates on the order of 100 gigabit per second and higher using a passive channel. Higher data transfer rates can be achieved using signal conditioner circuitry, such as a retimer or redriver, as described below.

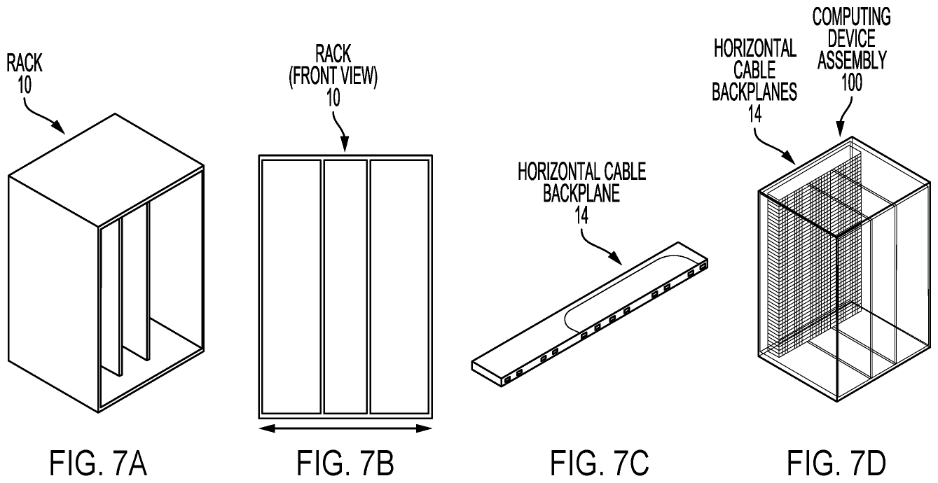

FIG. 7A shows a solid perspective view of the rack 10. FIG. 7B shows a front view of the rack 10. FIG. 7C shows a perspective view of the horizontal cable backplane 14. FIG. 7D shows a partially transparent perspective view of the computing device assembly 100 of FIG. 1 with only the horizontal cable backplanes 14 installed.

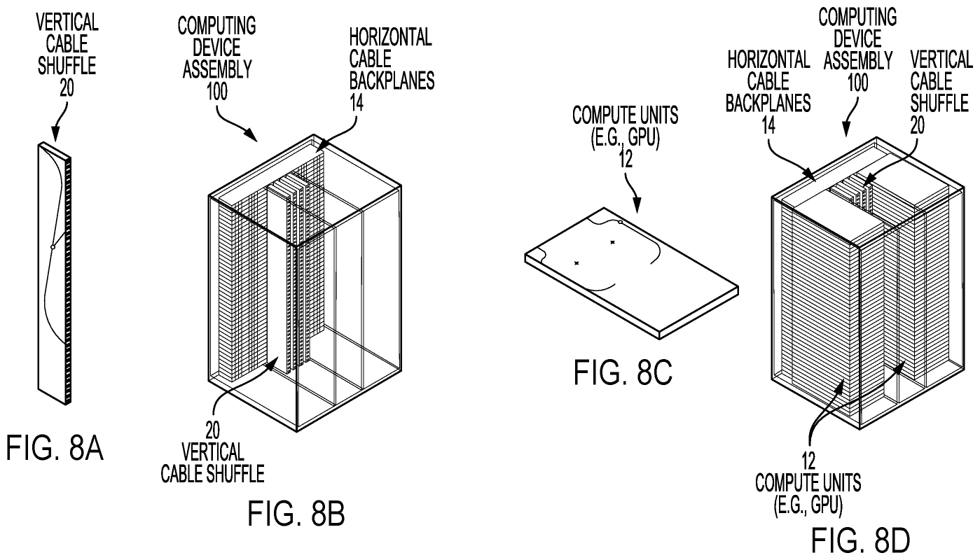

FIG. 8A shows a solid perspective view of the vertical cable shuffle 20 with an example cable illustrated therein. FIG. 8B shows a partially transparent perspective view of the computing device assembly of FIG. 1, with the horizontal cable backplanes 14 and vertical cable shuffles 20 installed. FIG. 8C shows a solid perspective view of a compute unit 12, with two example wires illustrated therein. FIG. 8D shows a partially transparent perspective view of the computing device assembly 100 of FIG. 1 with the compute units 12, vertical cable shuffles 20, and horizontal cable backplanes 14 installed.

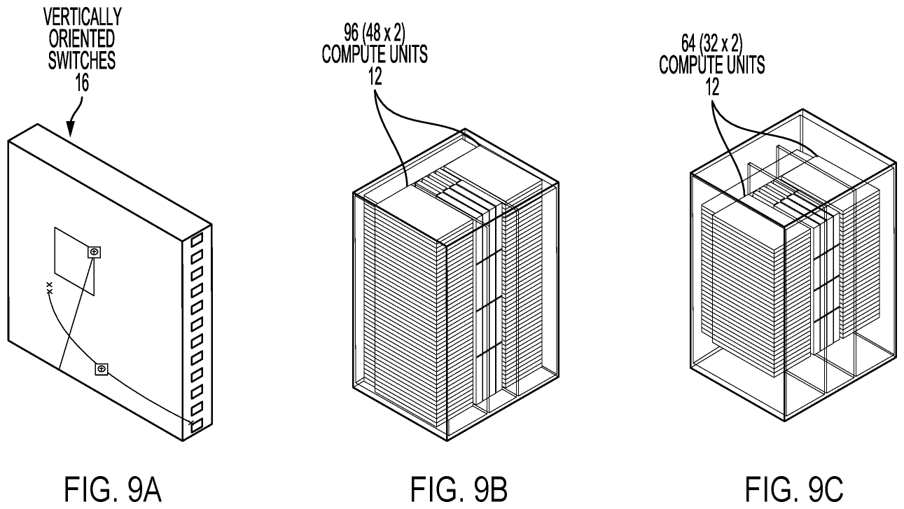

FIG. 9A shows a solid perspective view of the vertically oriented switch 16. In FIG. 9A the holes for the data connectors 40 are visible in the vertically oriented switch enclosure. One data connector 40 is provided for each layer on which a compute unit 12 is positioned. FIG. 9B shows a partially transparent perspective view of the computing device assembly 100 of FIG. 1, with 48×2=96 compute units 12 installed similarly to FIG. 1. FIG. 9C shows a modified version of the computing device assembly 100 of FIG. 9B with 32×2=64 compute units 12 installed. Typically, 64 or more compute units or 96 or more compute units are installed to increase the overall computing capacity of the assembled computing device assembly 100. However, it will be appreciated the other numbers of compute units 12, switches 16, and horizontal cable backplanes 14 may be provided in other configurations of the computing device assembly 100.

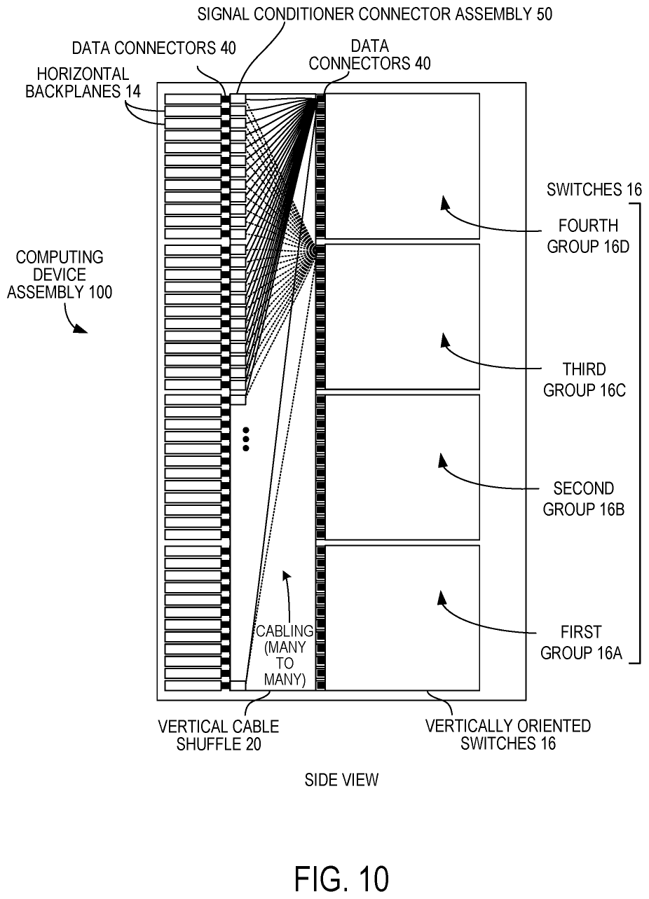

FIG. 10 shows a side view of an alternative configuration of the computing device assembly 100 of FIG. 3, taken along line 10-10 of FIG. 3. FIG. 10 shows signal conditioner connector assemblies 50 installed within each vertical cable shuffle 20. The signal conditioner connector assembly 50 may include a signal conditioner circuitry 60 (e.g., retimer, redriver). The retimer circuitry (which may perform equalization, clock recovery and signal regeneration based on the equalized and recovered clock signal) or redriver (i.e., reamplication) circuitry configured to retime or redrive the incoming signals, to thereby improve signal integrity. It will be appreciated that the signal-to-noise ratio at extremely high data rates can result in reduced signal integrity. The use of the signal conditioner connector assembly 50 at a location approximately 25%-75%, and more preferably 40%-60% along the cable path between the signal source (e.g., compute unit or switch) and the signal destination (e.g., switch or compute unit), provides the potential benefit of improving the integrity of the signal sufficiently to enable high data transfer rates of over 100 gigabit per second, and in some cases over 200 gigabit per second. Although the signal conditioner connector assembly 50 is shown inside the vertical cable shuffle 20 adjacent each data connector to the horizontal cable backplanes 14, it will be appreciated that alternatively the signal conditioner connector assembly 50 may be provided in between these components, or at a location within the horizontal cable backplane 14, for example.

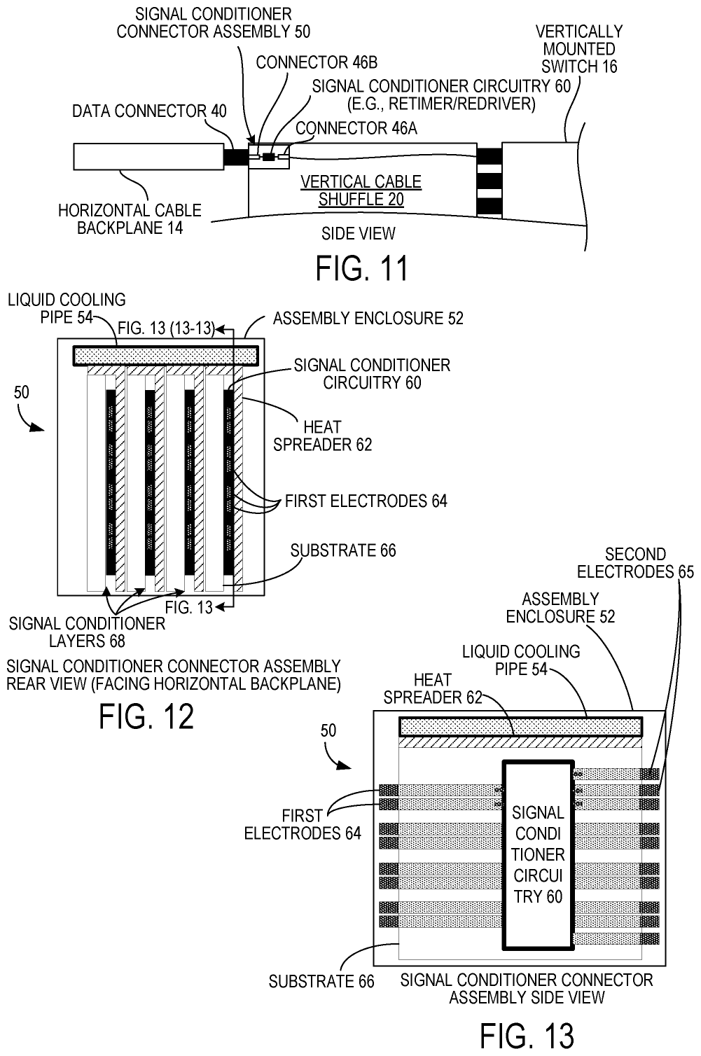

FIG. 11 shows a partial exploded schematic side view of the alternative configuration of the computing device assembly 100 shown in FIG. 10, schematically illustrating the signal conditioner connector assembly 50 in detail. As discussed above, the signal conditioner connector assembly 50 may include the signal conditioner circuitry 60 (e.g., retimer, driver). It will be appreciated that multiple wires connect to the signal conditioner connector assembly 50 via a switch side connector 46A and multiple corresponding wires connect to the connector assembly 50 via a horizontal cable backplane side connector 46B. To accommodate these multiple wires, a plurality of signal conditioner layers of electrodes are provided, which can be referred to as waffle layers in a waffle type connector enclosure, as described in relation to FIG. 12.

FIG. 12 shows a rear view of the signal conditioner connector assembly 50 of FIGS. 10 and 11, showing internal details. The signal conditioner connector assembly 50 includes an enclosure 52 and a plurality of signal conditioner layers 68 mounted within the assembly enclosure 52. The signal conditioner layers 68 are visible as viewed from the horizontal cable backplane 14. Each signal conditioner layer 68 includes a substrate 66 (e.g., printed circuit board wafer), a signal conditioner circuitry 60 mounted to the substrate 66, first electrodes 64 forming a first connector on a first side of the signal conditioner circuitry 60, second electrodes 65 forming a second connector on a second side of the signal conditioner circuitry 60, a heat spreader 62 in thermal communication with a side of the signal conditioner circuitry 60 opposite the substrate 66, and a liquid cooling pipe 54 positioned adjacent and in thermal communication with the heat spreader 62. The liquid cooling pipe 54 is configured to draw heat away from the heat spreader 62 for thermal management. The first electrodes 64 on the first side serve as the horizontal cable backplane connector 46B, and the second electrodes 65 on the second side serve as the switch side connector 46A. Performing signal retiming or redriving at extremely high data transfer rates can generate significant heat. To cool the components, the heat spreader 62 is provided in each waffle layer, which extends across a planar side of the signal conditioner circuitry 60 opposite the substrate 66, to a top side of the signal conditioner connector assembly 50. Across the top side of the signal conditioner connector assembly 50, the liquid cooling pipe 54 is oriented, which provides cooling liquid that flows through the liquid cooling pipe 54 and draws heat away from the head spreader 62, to cool the signal conditioner connector assembly 50.

FIG. 13 shows a schematic side view of the signal conditioner connector assembly 50 of FIGS. 10-12, showing internal details. This view is taken along line 13-13 of FIG. 12, and shows the electrodes 64 connecting to the signal conditioner circuitry 60 on each of the switch side and horizontal cable backplane side of the connector assembly 50.

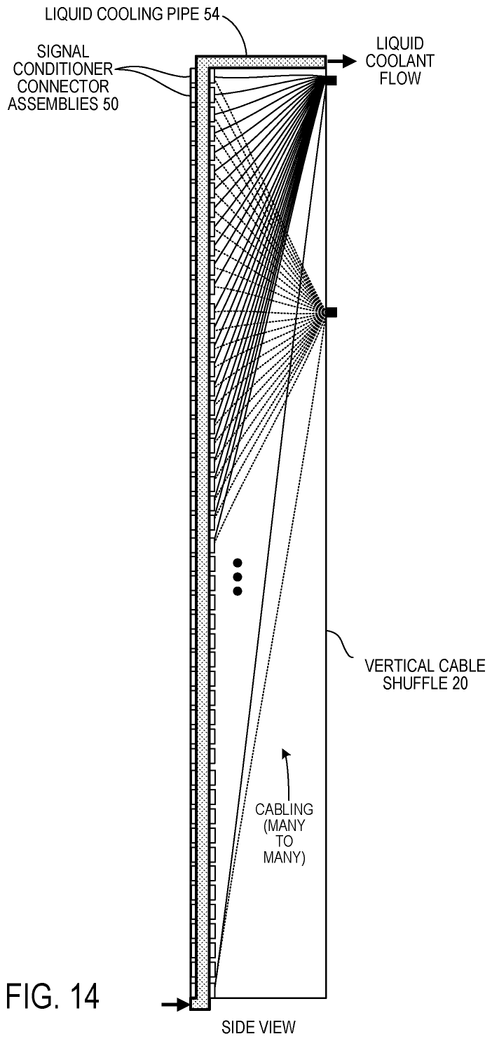

FIG. 14 is a side view of the vertical cable shuffle 20, showing a path of the liquid cooling pipe 54 to cool the signal conditioner connector assemblies 50. It will be appreciated that the liquid cooling pipe 54 extends from a top to a bottom of the vertical cable shuffle 20, and travels adjacent each of the signal conditioner connector assemblies 50. The pipe of FIG. 14 is fluidically connected to the liquid cooling pipe 54 of FIGS. 12 and 13, to thereby provide circulation across the top of each signal conditioner connector assembly 50. Alternatively, the signal conditioner connector assembly 50 could be rotated from the orientation shown in FIG. 12 and only a vertical cooling pipe could be used.

Although the signal conditioner connector assembly 50 is shown on all of the data connections 40 to the horizontal cable backplanes 14 from the vertical cable shuffle 20, in some configurations the signal conditioner connector assemblies 50 may be provided only on a set of data connections 40 for cable paths that are longer than a predetermined length. Thus, another set of shorter cable runs within the vertical cable shuffle 20 below the predetermined length may omit the signal conditioner connector assembly 50, while still maintaining signal integrity at certain data transfer rates.

It is believed that the above described computing device assembly 100 provides a technical benefit when used with high data transfer rate machine learning applications, such as large ML model training and inference, at speeds on the order of 100 gigabit per second and higher using a passive channel within a rack configured in the manner of rack 10 described above. Further, by using signal conditioning circuitry 60 as described above, such as a retimer or redriver, transfer rates of more than 100 gigabit per second can be achieved. In some cases, data transfer rates of more than 200 gigabit per second can be achieved. The location of the signal conditioning circuitry within the horizontal or vertical cable backplanes as described above, contributes to the significant increase in data transfer rates. With such high data transfer rates, the compute time required to train such models can be reduced.

The following paragraphs provide additional description of the subject matter of the present disclosure. One aspect provides a signal conditioning connector assembly including an enclosure and a plurality of signal conditioner layers mounted within the enclosure. According to this aspect, each signal conditioner layer may include a substrate and signal conditioner circuitry mounted to the substrate. Each signal conditioner layer may further include first electrodes forming a first connector on a first side of the signal conditioner circuitry and second electrodes forming a second connector on a second side of the signal conditioner circuitry. Each signal conditioner layer may further include a heat spreader in thermal communication with a side of the signal conditioner circuitry opposite the substrate. Each signal conditioner layer may further include a liquid cooling pipe positioned adjacent and in thermal communication with the heat spreader. The liquid cooling pipe may be configured to draw heat away from the heat spreader for thermal management.

According to this aspect, the signal conditioning circuitry may include retimer or redriver circuitry.

According to this aspect, the signal conditioner connector assembly may be provided adjacent an interface between a vertical cable shuffle and a horizontal cable backplane in a rack of a computing device assembly.

According to this aspect, the liquid cooling pipe may extend from a top to a bottom of the vertical cable shuffle.

According to this aspect, the substrate may be a printed circuit board.

According to this aspect, the heat spreader may extend across a planar side of the signal conditioner circuitry opposite the substrate.

According to this aspect, the liquid cooling pipe may be provided across a top side of the signal conditioning connector assembly.

According to this aspect, the first side of the signal conditioner circuitry may be a switch side of the connector assembly, and the second side of the signal conditioner circuitry may be a horizontal cable backplane side of the connector assembly.

According to this aspect, the signal conditioner connector assembly may be located at approximately 40%-60% along a cable path between a signal source and a signal destination.

According to another aspect of the present disclosure, a computing device assembly is provided. According to this aspect, the computing device assembly may include a rack. The computing device assembly may further include a plurality of compute units that are horizontally oriented and mounted within the rack in one of two vertical stacks. The computing device assembly may further include a plurality of switches that are vertically oriented and mounted along a front side of the rack laterally between the two vertical stacks of compute units. The computing device assembly may further include a plurality of horizontal cable backplanes mounted in a vertical stack along a rear side of the rack. The computing device assembly may further include a plurality of vertical cable shuffles mounted between the two vertical stacks of compute units and between the vertically oriented switches and the vertical stack of horizontal cable backplanes. Each of the plurality of vertical cable shuffles may include a signal conditioner connector assembly. According to this aspect, the signal conditioner connector assembly may include an enclosure and a plurality of signal conditioner layers mounted within the enclosure. Each signal conditioner layer may include a substrate and signal conditioner circuitry mounted to the substrate. Each signal conditioner layer may further include first electrodes forming a first connector on a first side of the signal conditioner circuitry and second electrodes forming a second connector on a second side of the signal conditioner circuitry. Each signal conditioner layer may further include a heat spreader in thermal communication with a side of the signal conditioner circuitry opposite the substrate. Each signal conditioner layer may further include a liquid cooling pipe positioned adjacent and in thermal communication with the heat spreader. The liquid cooling pipe may be configured to draw heat away from the heat spreader for thermal management.

According to this aspect, the signal conditioning circuitry may include retimer or redriver circuitry.

According to this aspect, the signal conditioner connector assembly may be provided adjacent an interface between one of the vertical cable shuffles and one the horizontal cable backplanes.

According to this aspect, the liquid cooling pipe may extend from a top to a bottom of the vertical cable shuffle.

According to this aspect, the substrate may be a printed circuit board.

According to this aspect, the heat spreader may extend across a planar side of the signal conditioner circuitry opposite the substrate.

According to this aspect, the liquid cooling pipe may be provided across a top side of the signal conditioner connector assembly.

According to this aspect, the first side of the signal conditioner circuitry may be a switch side of the connector assembly, and the second side of the signal conditioner circuitry may be a horizontal cable backplane side of the connector assembly.

According to this aspect, the vertical cable shuffles may be elongated in depth and vertical dimensions of the rack.

According to this aspect, the signal conditioner connector assembly may be located at approximately 40%-60% along a cable path between a signal source and a signal destination.

According to this aspect, a lateral dimension of each of the compute units may be approximately ¼ to ⅓ of a lateral dimension of the rack, and a depth dimension of each of the compute units may be approximately 60-90% of the rack.

“And/or” as used herein is defined as the inclusive or V, as specified by the following truth table:

| A | B | A ∨ B |
|---|---|---|
| True | True | True |
| True | False | True |
| False | True | True |
| False | False | False |

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A signal conditioning connector assembly, comprising:
an enclosure; and
a plurality of signal conditioner layers mounted within the enclosure, each signal conditioner layer including:
a substrate;
signal conditioner circuitry mounted to the substrate;
first electrodes forming a first connector on a first side of the signal conditioner circuitry;
second electrodes forming a second connector on a second side of the signal conditioner circuitry;
a heat spreader in thermal communication with a side of the signal conditioner circuitry opposite the substrate; and
a liquid cooling pipe positioned adjacent and in thermal communication with the heat spreader, the liquid cooling pipe being configured to draw heat away from the heat spreader for thermal management.

2. The signal conditioning connector assembly of claim 1, wherein the signal conditioning circuitry includes retimer or redriver circuitry.

3. The signal conditioning connector assembly of claim 1, wherein the signal conditioner connector assembly is provided adjacent an interface between a vertical cable shuffle and a horizontal cable backplane in a rack of a computing device assembly.

4. The signal conditioning connector assembly of claim 3, wherein the liquid cooling pipe extends from a top to a bottom of the vertical cable shuffle.

5. The signal conditioning connector assembly of claim 1, wherein the substrate is a printed circuit board.

6. The signal conditioning connector assembly of claim 1, wherein the heat spreader extends across a planar side of the signal conditioner circuitry opposite the substrate.

7. The signal conditioning connector assembly of claim 1, wherein the liquid cooling pipe is provided across a top side of the signal conditioning connector assembly.

8. The signal conditioning connector assembly of claim 1, wherein the first side of the signal conditioner circuitry is a switch side of the connector assembly, and the second side of the signal conditioner circuitry is a horizontal cable backplane side of the connector assembly.

9. The signal conditioning connector assembly of claim 1, wherein the signal conditioner connector assembly is located at approximately 40%-60% along a cable path between a signal source and a signal destination.

10. A computing device assembly, comprising:
a rack;
a plurality of compute units that are horizontally oriented and mounted within the rack in one of two vertical stacks;
a plurality of switches that are vertically oriented and mounted along a front side of the rack laterally between the two vertical stacks of compute units;
a plurality of horizontal cable backplanes mounted in a vertical stack along a rear side of the rack; and
a plurality of vertical cable shuffles mounted between the two vertical stacks of compute units and between the vertically oriented switches and the vertical stack of horizontal cable backplanes, each of the plurality of vertical cable shuffles including a signal conditioner connector assembly, wherein
the signal conditioner connector assembly comprises:
an enclosure; and
a plurality of signal conditioner layers mounted within the enclosure, each signal conditioner layer including:
a substrate;
signal conditioner circuitry mounted to the substrate;
first electrodes forming a first connector on a first side of the signal conditioner circuitry;
second electrodes forming a second connector on a second side of the signal conditioner circuitry;
a heat spreader in thermal communication with a side of the signal conditioner circuitry opposite the substrate; and
a liquid cooling pipe positioned adjacent and in thermal communication with the heat spreader, the liquid cooling pipe being configured to draw heat away from the heat spreader for thermal management.

11. The computing device assembly of claim 10, wherein the signal conditioning circuitry includes retimer or redriver circuitry.

12. The computing device assembly of claim 10, wherein the signal conditioner connector assembly is provided adjacent an interface between one of the vertical cable shuffles and one the horizontal cable backplanes.

13. The computing device assembly of claim 10, wherein the liquid cooling pipe extends from a top to a bottom of the vertical cable shuffle.

14. The computing device assembly of claim 10, wherein the substrate is a printed circuit board.

15. The computing device assembly of claim 10, wherein the heat spreader extends across a planar side of the signal conditioner circuitry opposite the substrate.

16. The computing device assembly of claim 10, wherein the liquid cooling pipe is provided across a top side of the signal conditioner connector assembly.

17. The computing device assembly of claim 10, wherein the first side of the signal conditioner circuitry is a switch side of the connector assembly, and the second side of the signal conditioner circuitry is a horizontal cable backplane side of the connector assembly.

18. The computing device assembly of claim 10, wherein the vertical cable shuffles are elongated in depth and vertical dimensions of the rack.

19. The computing device assembly of claim 10, wherein the signal conditioner connector assembly is located at approximately 40%-60% along a cable path between a signal source and a signal destination.

20. The computing device assembly of claim 10, wherein a lateral dimension of each of the compute units is approximately ¼ to ⅓ of a lateral dimension of the rack, and a depth dimension of each of the compute units is approximately 60-90% of the rack.
